(19) United States
(12) Patent Application Publication
(10) Pub. No.: US 2005/0223306 A1
(43) Pub. Date: Oct. 6, 2005

(54) Communications apparatus, systems, and methods

(76) Inventor: Luiz M. Franca-Neto, Sunnyvale, CA (US)

Correspondence Address: SCHWEGMAN, LUNDBERG, WOESSNER & KLUTH, P.A., P.O. BOX 2938, MINNEAPOLIS, MN, 55402-0938, US

(21) Appl. No.: 10/814,114

(22) Filed: Mar. 30, 2004

(51) Int. Cl. H03M 13/00

(52) U.S. Cl. 714/784

(57) ABSTRACT

In some embodiments, an apparatus and a system, as well as a method and an article, may include translating a bit stream into a multi-tone communications signal having a substantially simultaneous multi-tone signaling bandwidth of greater than about 20 percent of an associated carrier frequency. In some embodiments, an apparatus and a system, as well as a method and an article, may include determining a presence of a plurality of tones included in a multi-tone communications signal by comparing a combined amount of two measured orthogonal signal components to a threshold value.

### TECHNICAL FIELD

Various embodiments described herein relate to communications generally, including apparatus, systems, and methods for transmitting and receiving information.

### BACKGROUND INFORMATION

Wireless communication devices may use wide-bandwidth communication techniques to accommodate the trend toward ever-increasing data rates. For example, data rates have been targeted to surpass 1 Gigabit/second over the 3 GHz to 10 GHz band allocated by the Unites States Federal Communications Commission for ultra-wide-band communications.

At high data rates, sophisticated reception circuitry may be required to maintain signal integrity. The presence of in-band signal blockers, as well as the use of relatively large passive components may combine to render efficient complementary metal-oxide semiconductor (CMOS) designs difficult. As a result, physical layer signal processing tasks may be allocated to the network layer processor to reduce the circuit area that might otherwise be needed. Thus, there is a need to develop wide-band communications circuitry that is CMOS-friendly to promote the efficient use of die area, as well as processor task allocation.

### BRIEF DESCRIPTION OF THE DRAWINGS

FIG. 1 is a block diagram of a transmission apparatus according to various embodiments;

FIG. 2 is a block diagram of a reception apparatus according to various embodiments;

FIG. 3 is a schematic and block diagram of a detector according to various embodiments;

FIG. 4 is a block diagram of various apparatus and systems according to several embodiments;

FIGS. 5A and 5B are flow charts illustrating several methods according to various embodiments; and

FIG. 6 is a block diagram of an article according to various embodiments.

### DETAILED DESCRIPTION

Some embodiments of the invention disclosed herein may address a few of the challenges described above by providing a compact, high-data rate ultra-wide-band (UWB) transceiver. The transceiver, including multi-tone transmission and reception apparatus, may be produced compactly since the use of large passive components can be avoided in many embodiments by taking advantage of CMOS integration. UWB communication may be accomplished by transmitting simultaneous multi-tone signals, and reception may occur via limited front-end amplification and baseband conversion prior to adding further gain for robust communications in the presence of in-band blockers. Tone decoding apparatus may be constructed using combinatorial logic.

In some embodiments of reception apparatus, an averaging automatic gain control (A-AGC) mechanism may be implemented. Reception augmented by the A-AGC may allow discarding jammed or canceled tones from decoder consideration, providing even greater robustness in transmissions within hostile environments.

Due to the greater integration which may be achieved in some embodiments, physical layer signal processing may be accomplished via wired architecture, while the processor, perhaps located on the same die as the transceiver, is free to execute upper-level network layer tasks. Multiple piconets may even be accommodated in a single area by coordination on the media access network level, with or without synchronization.

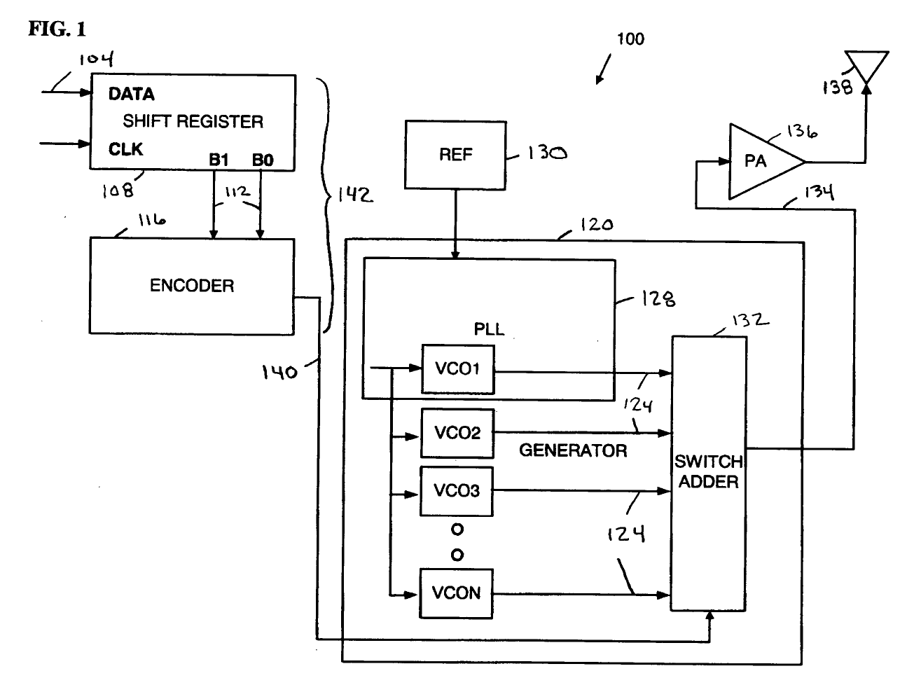

FIG. 1 is a block diagram of a transmission apparatus 100 according to various embodiments which may operate in the manner previously described. As shown, a first bit stream 104 to be communicated may be provided to a shift register 108 such that each set of two bits in the first bit stream 104 define a group 112 of data to be received by the encoder 116. The data group 112 may be used by the encoder 116 to pass operate a switch 132 defining the UWB symbols as groups of tones 124.

In other embodiments, instead of two bits, a larger number of bits from the bit stream 104 may be used to produce UWB symbols. Thus, for the purposes of this document, a “UWB symbol” may comprise a defined set of multi-tones to be transmitted simultaneously. The definition may be expressed in the programming of the encoder 116, as it translates data groups 112 into an output 140 to control the switch 132.

Each tone 124 may be created using a set of voltage-controlled oscillators (VCOs) VCO1, VCO2, . . . , VCON designed with substantially identical active nodes, and capacitive loading proportional to the ratios of their nominal frequency of operation, for example. In some embodiments, only the VCO having the highest operating frequency (e.g., VCO1 operating at 10 GHz) may form a portion of a phase-locked loop (PLL) 128 driven by a frequency reference 130. Since ratio matched capacitive loading may be adjusted so that the slave VCOs VCO2, VCO3, . . . , VCON produce tones frequencies related as a ratio to the frequency of the master VCO VCO1, the slave VCOs VCO2, VCO3, . . . , VCON may operate to track the master VCO VCO1 and provide their correct tones' frequency whenever the master VCO VCO1 locks onto its design frequency (e.g., 10 GHz). For example, if the frequency of VCO1 is about 10 GHz, the frequency of VCO2 might be about 8 GHz ( 8/10 of VCO1 frequency), the frequency of VCO3 might be about 6 GHz ( 6/10 of VCO1 frequency), and the frequency of VCON might be about 4 GHz ( 4/10 of VCO1 frequency), such that all of the tones fall within allocated band limits of about 3 GHz to about 10 GHz. Of course, other master oscillator frequencies and slave ratio frequencies may be selected.

The number of tones 124 may be a function of many variables. In general, the more tones 124 that are used, the more robust signaling can be, such that interference from other sources, including multi-path problems, can be reduced. Increased signal integrity may be achieved at the cost of circuit duplication. In CMOS and other types of fabrication, the desired ratio of capacitive loading may depend on the characteristic that devices located on the same die are usually substantially similar (e.g., well-matched). Thus, while the absolute frequency of the master VCO VCO1 may or may not be locked to a selected value (e.g., using a PLL 128), the slaves VCO2, VCO3, . . . , VCON may follow the master VCO1 in a fairly predictable fashion, keeping substantially fixed ratios from their frequencies to the master VCO. Note however that if the number of tones is increased significantly, instead of using independent VCOs for every tone, it may become desirable to use an IFFT (inverse Fast Fourier Transform) block and a digital to analog converter (DAC) to produce UWB symbols 134. Analogously, an analog to digital converter (ADC) and a fast Fourier transform (FFT) block may be implemented in the receiving-end of a transceiver to decode such symbols.

It is to be noted that if ON/OFF modulation is assumed, and UWB symbols are coded as di-bits (e.g., two bit symbols), each tone may be present in half (or less) of the UWB tones, which may be set apart by about 500 MHz. In this manner, data communication rates of about 1 Gigabit/second may be achieved, considering self-inflicted interference, and ignoring noise levels and distortion.

It should also be noted that as the number of tones increase, and the bit rate increases, the available bandwidth for each tone decreases. However, the overall signaling bandwidth tends to remain the same.

After the tones 124 are generated, they may be permitted to pass through the switch 132 so as to form a multi-tone communications signal 134, perhaps to be received by a power amplifier 136, and transmitted via an antenna 138 such as a patch, monopole, dipole, beam, array, or directional antenna, among others, into space. In some embodiments, the switch 132 may operate to select one, some, or all of the tones 124 provided by the VCOs VCO1, VCO2, . . . , VCON based on the encoder's output 140 according to a preselected coding arrangement. The switch may operate to add the tones 124 together so as to produce the desired multi-tone communications signal 134.

Therefore, in some embodiments of the invention, a transmission apparatus 100 may include a multi-bit encoder 116 coupled to a multi-tone generator 120 to provide a multi-tone communications signal 134 having a substantially simultaneous multi-tone signaling bandwidth of greater than about 20 percent of an associated carrier frequency. For example, in some embodiments, if the carrier frequency is about 5 GHz, the signaling bandwidth may be greater than about 1 GHz. In some embodiments, for example, multi-tone simultaneous signaling from 3 GHz to 10 GHz may correspond to a 7 GHz bandwidth signal on top of an implicit 6.5 GHz carrier.

In some embodiments, a multi-bit encoder 142 (perhaps including the shift register 108 and the encoder 116) may be used to receive a first bit stream 104 and to provide a second bit stream 140 having data presented as one or more groups of substantially simultaneous bits (e.g., symbols). Thus, in some embodiments, the multi-bit encoder may include a shift register 108.

In some embodiments, a multi-tone generator 120 may include a master oscillator VCO1 and one or more slave oscillators VCO2, VCO3, . . . . , VCON. The multi-tone generator 120 may operate to generate a plurality of tones 124 responsive to the second bit stream 140. As noted previously, the number of tones 124 can depend on a number of factors, but in many embodiments, the plurality of tones 124 may include a number of tones (e.g., 6) greater than a number of possible states of the data in the second bit stream (e.g., 4 states for a di-bit encoder 116). Increasing the number of tones may result in a more robust communication system, perhaps providing a reduced bit error rate (BER), since redundant sets of tones may be used to indicate the same data states, if desired. As shown in FIG. 1, for example, every two bits in the first bit stream 104, or di-bit, may be transmitted as a multitone UWB symbol coded in the second bit stream 140.

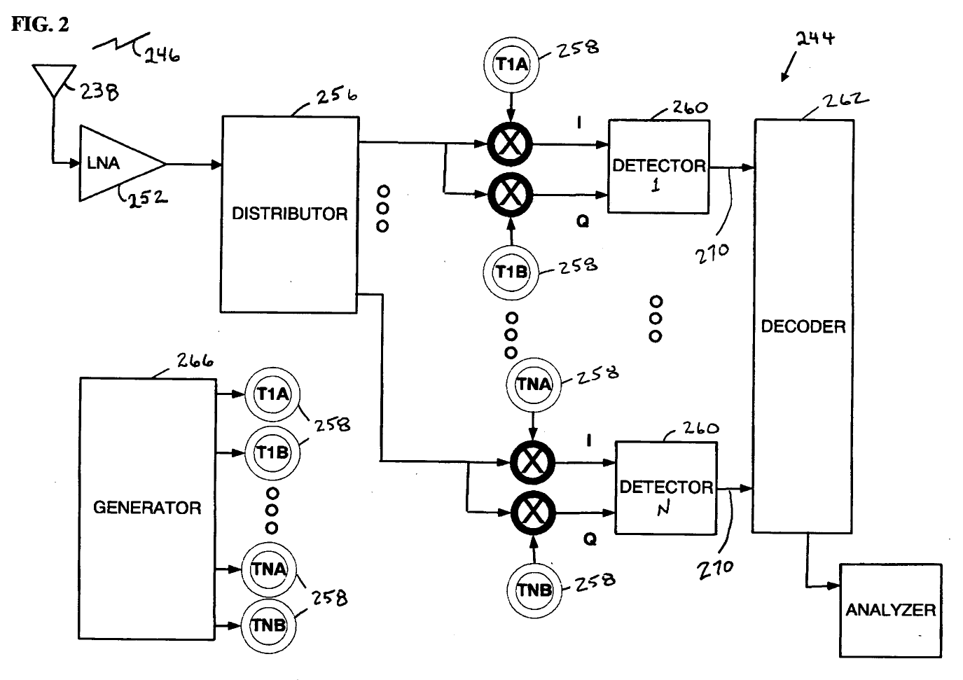

FIG. 2 is a block diagram of a reception apparatus 244 according to various embodiments which may operate in the manner previously described. In some embodiments, a multi-tone communications signal 246 (similar to or identical to the signal 134 of FIG. 1) may be received by an antenna 238 (similar to or identical to the antenna 138 of FIG. 1), perhaps amplified slightly by a broad band low-noise amplifier (LNA) 252 so as to cover a bandwidth of about 3 GHz to about 10 GHz, providing sufficient gain to define the noise figure performance of the receiver for each of the tones to be detected.

The output of the LNA 252 may be used to feed a signal distributor 256, which in turn may pass the received multi-tone communications signal 246 to a plurality of separate detectors 260 after mixing down to baseband using the tones 258 provided by a generator 266. Each detector DETECTOR1 . . . DETECTORN may comprise a phasor detector independently dedicated to one of the tones used in the multi-tone UWB symbol signaling mechanism disclosed herein. After the presence/absence of the desired tones are detected by the detectors 260, the results can be delivered to a decoder 262, which may operate on a “voting” principle to determine whether a particular symbol was indeed received. As will be demonstrated below, the detectors 260 may be designed using combinatorial logic to determine which UWB symbols have been received (based on the absence/presence of tones and their orthogonal counterparts) to provide the decoder 262 with indications of detected tones 270.

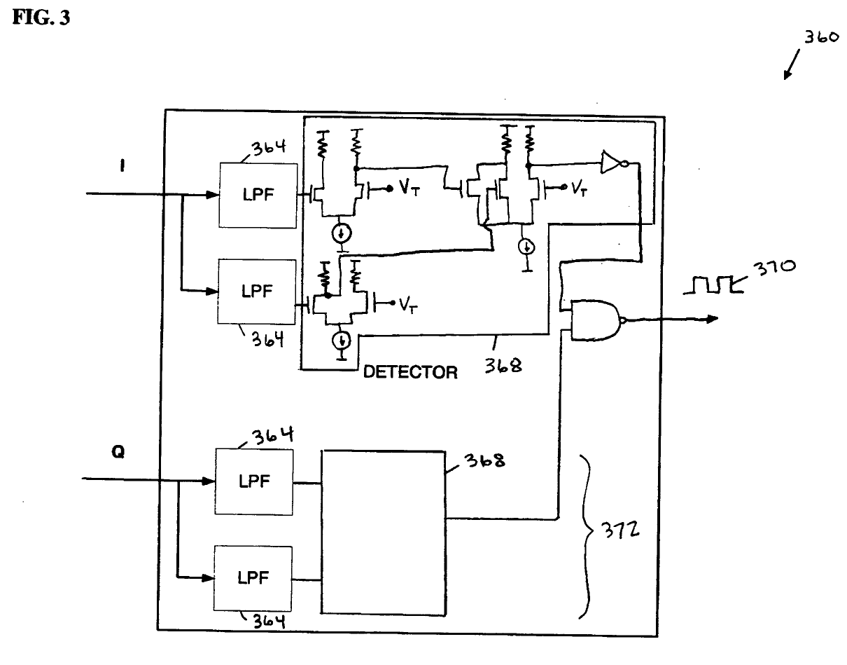

FIG. 3 is a schematic and block diagram of a detector 360 according to various embodiments. The detector 360 may be similar to or identical to the detectors 260 of FIG. 2.

Referring now to FIGS. 1, 2, and 3, it should be noted that for the sake of simplicity, signaling is assumed to be ON/OFF modulation of a tone to be received. Other types of modulation, including amplitude and phase modulation, for example, may be used.

Unknowns with respect to the received signal 246 may include the signal propagation delay from the transmission apparatus 100 to the reception apparatus 244, and frequency drift of the tones 124 as they are generated in the transmission apparatus 100, and the corresponding tones 258 generated in the reception apparatus 244 (e.g., tone drift may occur as the transmission apparatus 100 drifts closer to or further apart from the reception apparatus 244). Therefore, the task of the detectors 260 is to detect whether a tone 124 has been sent, or not, regardless of time delays and frequency drift. This may be accomplished by using a pair of orthogonal functions during the task of down-conversion to baseband, such as the sine function for the in-phase signal I, and the cosine function for the quadrature signal Q.

It should be noted that any pair of substantially orthogonal functions may be used with respect to the detectors 260, 360. The intent is not necessarily to gather information from the phase of a received tone signal, but only to detect its presence or absence, regardless of the included phase. If only one function is detected (e.g., either I or Q, but not both), then tones having a phase orthogonal to that being detected might be missed.

For simplicity and the purposes of discussion, assume a single-tone communication system. After a receiver has amplified the single-tone signal received by the antenna, and mixed it down to baseband, low-pass filters 364 may be used to reject undesired frequencies in the in-phase I and quadrature Q signals. In each detector 260, 360, positive and negative voltage swings may be detected by circuitry 368 in the in-phase I and quadrature Q channels so as not to miss phases which may be present. In this way, by dedicating a detector 260, 360 to each detected tone 370, even though blocking interference may operate to jam a limited number of tones T1, . . . , TN in the reception apparatus 244, UWB symbols in the received signal 246 may still be detected in the presence of surviving tones.

Therefore, as shown in FIG. 2, in some embodiments of the invention, a reception apparatus 244 may include a plurality of detectors 260 to determine the presence of a plurality of detected tones 270 (similar to or identical to the detected tone 370 in FIG. 3) included in a multi-tone communications signal 246 by comparing a combined amount of two measured orthogonal signal components I and Q to a selected threshold value. The threshold value may be determined by a bias signal V_{T} used in the detector 360.

As can be seen in FIG. 3, in some embodiments, the detectors 360 may include one or more quadrature detectors 372. As noted previously, the measured orthogonal signal components may include a sine component (e.g., the I component) and a cosine component (e.g., the Q component).

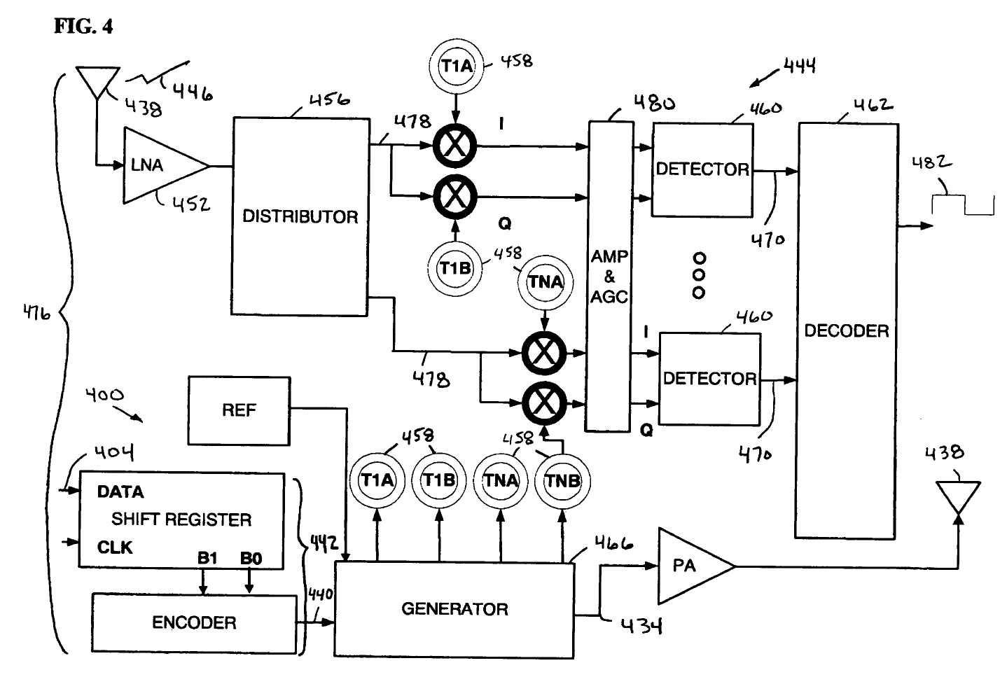

FIG. 4 is a block diagram of various apparatus 400, 440 and systems 476 according to several embodiments. In some embodiments, a system 476 may include one or more transmission apparatus 400 (which may be similar to or identical to the transmission apparatus 100 described with respect to FIG. 1). Similarly, in some embodiments, a system 476 may include one or more reception apparatus 444 (which may be similar to or identical to the reception apparatus 244 described with respect to FIG. 2).

Upon inspecting FIG. 4, two differences from the previous discussion may become apparent. First, the generator 466 may be shared between the transmission apparatus 400 and the reception apparatus 444, perhaps obviating the need for unnecessary repetition in the circuit design of the system 476. Thus, in some embodiments, the in-phase tones T1A, . . . , TNA and the quadrature tones T1B, . . . , TNB may be generated by a generator 466 and used, in combination with the symbols 440 provided by the multi-tone encoder 442, to create a multi-tone communications signal 434. In addition, the in-phase tones T1A, . . . , TNA and the quadrature tones T1B, . . . , TNB may be generated by the generator 466 and used to mix with the distributed signals 478 (e.g., similar to or identical to an amplified or non-amplified version of the multi-tone communications signal 446) to provide in-phase I and quadrature Q baseband signals for presentation to the detectors 460.

Second, an amplifier 480, perhaps including an A-AGC may be introduced into the reception apparatus 444 to further improve performance. The A-AGC may operate to impose substantially equal gain on baseband amplifiers (perhaps included in the amplifier 480) used to amplify baseband I and Q signals before presenting them to the detectors 460. Use of the A-AGC detector can assist in the identification of jammed and/or canceled tones so that they are ignored by appropriate detectors 460 in determining which symbols have in fact been received.

For example, the decoder 462 may include one or more counters or time bases to count the number of times detected tones change state (e.g., toggle) within a given time window. Excessive toggling, and/or a lack of activity may be used by the decoder 462 to discard tones which might otherwise appear to be detected by the detectors 460. The correct amount of toggling may be determined, for example, by comparing determined toggling rates with an average toggling rate for some number of the tones.

Using prior knowledge of valid UWB symbols, the bit error rate (BER) of the communication link can be estimated. This estimated BER may be used to negotiate the data communication rate between a transmission apparatus 400 and a reception apparatus 444. By adding memory to register the states in the detector 360, the UWB system illustrated can be extended to detect amplitude modulated tones for even higher data communication rates.

Thus, in some embodiments, a system 476 may include a multi-bit encoder 442 coupled to a multi-tone generator 466 to provide a first multi-tone communications signal 434 having a substantially simultaneous multi-tone signaling bandwidth of greater than about 20 percent of an associated carrier frequency. The system 476 may include a plurality of detectors 460, such as phasor detectors, to determine a presence of a plurality of tones 458 included in a second multi-tone communications signal 446 by comparing a combined amount of two measured orthogonal signal components I and Q to a selected threshold value. The system 476 may also include one or more antennas 438 to transmit the first multi-tone communications signal 434 and to receive the second multi-tone communications signal 446. As noted above, the antennas 438 may be of many types, including patch, monopole, dipole, beam, array, or directional antenna, among others.

In some embodiments, the system 476 may include an amplifier 480 having an average automatic gain control to receive one or more multi-tone communications signals 478 from a distribution module 456 and to apply a substantially equal gain to the plurality of tones. Thus, in some embodiments, the distribution module 456 may be coupled to the antenna 438 and to provide the second multi-tone communications signal 446 (perhaps amplified by an LNA 452) to the plurality of detectors 460.

In some embodiments, the system 476 may include a determination module, perhaps in the form of a decoder 462, to receive multiple indications 470 of the presence of the plurality of tones T1, . . . , TN from the plurality of detectors 460 and to determine a received data output 482 corresponding to the multiple indications 470. As noted previously, the plurality of tones T1, . . . , TN may include a number of tones many times greater than the number of possible states of the data 404. For example, the plurality of tones T1, . . . , TN may include a number of tones about two times the number of possible states of the data 404 (e.g., eight tones and four possible data states in a di-bit system).

The transmission apparatus 100, 400, bit streams 104, 140, 404, shift register 108, groups 112, encoder 116, tone generator 120, multi-tones 124, PLL 128, switch 132, multi-tone communications signals 134, 246, 434, 446, power amplifier 136, antennas 138, 238, 438, multi-bit encoders 142, 442, reception apparatus 244, 444, LNAs 252, 452, signal distributors 256, 456, tones 258, 458, detectors 260, 360, DETECTOR1 . . . DETECTORN, decoders 262, 462, circuitry 368, detected tones 270, 370, 470, quadrature detector 372, generators 266, 466, system 476, distributed signals 478, amplifier 480, in-phase I and quadrature Q signals, in-phase tones T1A, . . . , TNA, quadrature tones T1B, . . . , TNB, tones T1, . . . , TN, and oscillators VCO1, VCO2, . . . , VCON may all be characterized as “modules” herein. Such modules may include hardware circuitry, and/or a processor and/or memory circuits, software program modules and objects, and/or firmware, and combinations thereof, as desired by the architect of the apparatus 100, 244, 400, 444 and systems 476, and as appropriate for particular implementations of various embodiments. For example, in some embodiments, such modules may be included in a system operation simulation package, such as a software electrical signal simulation package, a power usage and distribution simulation package, a capacitance-inductance simulation package, a power/heat dissipation simulation package, and/or a combination of software and hardware used to simulate the operation of various potential embodiments.

It should also be understood that the apparatus and systems of various embodiments can be used in applications other than for systems that include wireless data communications, and thus, various embodiments are not to be so limited. The illustrations of apparatus 100, 244, 400, 444 and systems 476 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, processor modules, embedded processors, data switches, and application-specific modules, including multilayer, multi-chip modules. Such apparatus and systems may further be included as sub-components within a variety of electronic systems, such as televisions, cellular telephones, personal computers, workstations, radios, video players, vehicles, and others. Some embodiments include a number of methods.

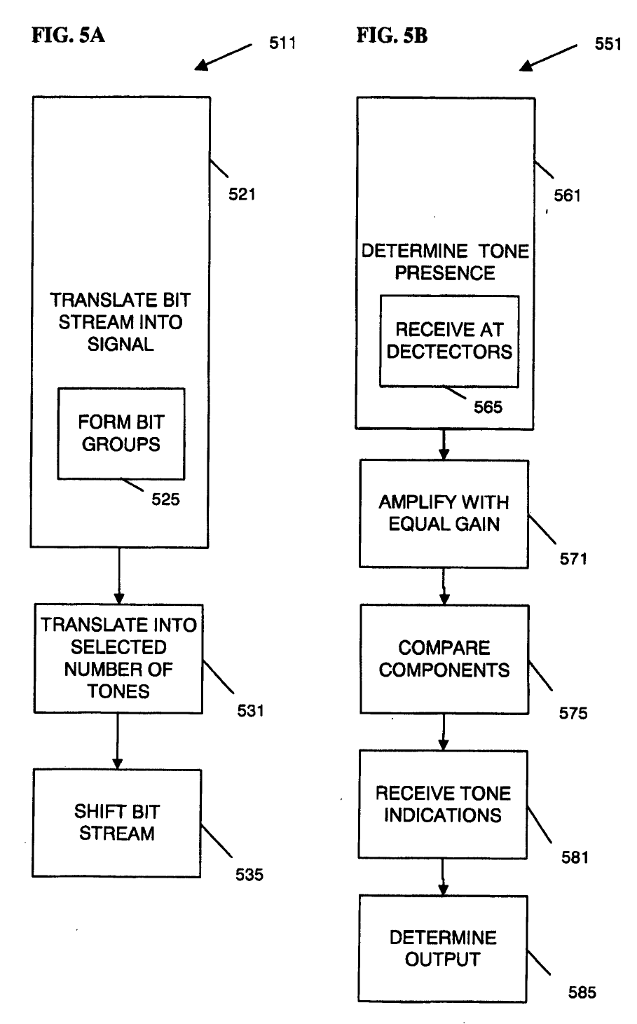

For example, FIGS. 5A and 5B are flow charts illustrating several methods according to various embodiments. For example, in some embodiments of the invention, a method 511 may (optionally) begin at block 521 with translating a first bit stream into a multi-tone communications signal having a substantially simultaneous multi-tone signaling bandwidth of greater than about 20 percent of an associated carrier frequency. Translating the first bit stream at block 521 may further include translating the first bit stream into a second bit stream having data presented as one or more groups of substantially simultaneous bits at block 525, including at least two groups of substantially simultaneous bits (e.g., symbols).

In some embodiments, the method 511 may include translating the second bit stream into a multi-tone communications signal, such that the translated signal comprises a number of substantially simultaneous tones less than or equal to a maximum number of the substantially simultaneous bits at block 531. In some embodiments, the method 511 may include shifting the first bit stream to provide the second bit stream at block 535. Other embodiments may be realized.

For example, in some embodiments of the invention, a method 551 may (optionally) begin at block 561 with receiving a multi-tone communications signal at a plurality of detectors, including phasor detectors, to determine a presence of a number of substantially simultaneous tones included in a multi-tone communications signal. Determining the presence of the substantially simultaneous tones at block 561 may further include receiving the multi-tone communications signal at a plurality of detectors, including phasor dectectors, at block 565.

In some embodiments, the method 551 may include amplifying the multi-tone communications signal using an approximately equal gain (e.g., applying an A-AGC) at block 571. For example, an approximately equal gain may be applied to the tones included in the multi-tone communications signal by implementing an AGC for each bandpass stage associated with the phasor detector for each tone. In some embodiments, this activity may be performed prior to comparing a combined amount (e.g., a phasor combination) of two measured orthogonal signal components in at least one of the number of substantially simultaneous tones to a threshold value at block 575.

In some embodiments, the method 551 may include receiving multiple indications of the presence of the plurality of tones from a plurality of detectors, including phasor detectors, at block 581. In some embodiments, the method 551 may include determining a received data output corresponding to the multiple indications at block 585.

It should be noted that the methods described herein do not have to be executed in the order described, or in any particular order. Moreover, various activities described with respect to the methods identified herein can be executed in serial or parallel fashion. Information, including parameters, commands, operands, and other data, can be sent and received in the form of one or more carrier waves.

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment. Thus, other embodiments may be realized.

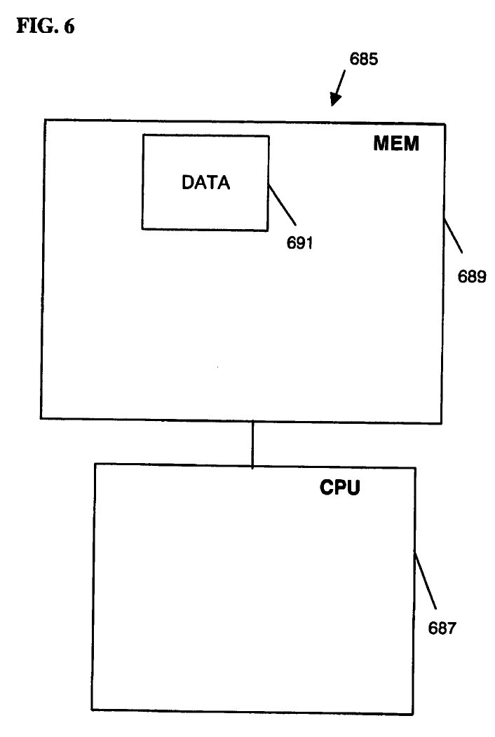

FIG. 6 is a block diagram of an article 685 according to various embodiments, such as a computer, a memory system, a magnetic or optical disk, some other storage device, and/or any type of electronic device or system. The article 685 may include a processor 687 coupled to a machine-accessible medium such as a memory 689 (e.g., removable storage media, as well as any memory including an electrical, optical, or electromagnetic conductor) having associated information 691 (e.g., computer program instructions and/or data), which when accessed, results in a machine (e.g., the processor 687) performing such actions as determining the presence of a plurality of tones included in a multi-tone communications signal by comparing a combined amount of two measured orthogonal signal components to a threshold value. As noted previously, determining the presence of the plurality of tones may include receiving the multi-tone communications signal at a plurality of phasor detectors, as well as amplifying the multi-tone communications signal using an approximately equal gain prior to comparing the orthogonal signal components. Other activities may include receiving multiple indications of the presence of the plurality of tones from the plurality of detectors, as well as determining a received data output corresponding to the multiple indications.

In some embodiments, the article 685 may include a processor 687 coupled to a machine-accessible medium such as a memory 689 (e.g., a memory including an electrical, optical, or electromagnetic conductor) having associated information 691 (e.g., computer program instructions and/or data), which when accessed, results in a machine (e.g., the processor 687) performing such actions as translating a first bit stream into a multi-tone communications signal having a substantially simultaneous multi-tone signaling bandwidth of greater than about 20 percent of an associated carrier frequency. As noted previously, translating the first bit stream may further include translating the first bit stream into a second bit stream having data presented as at least two groups of substantially simultaneous bits. Further activities may include translating the second bit stream into the multi-tone communications signal comprising a number of substantially simultaneous tones less than or equal to a maximum number of the substantially simultaneous bits.

Improved circuit integration, such as locating scalable portions of transmitters, receivers, and transceivers on the same die as a processor may result from implementing the apparatus, systems, and methods disclosed herein. Some embodiments may be realized such that only transistors and other scalable components remain on-die, permitting further integration of high-performance, high-power CMOS integrated radios, capable of robust communications in the face of interference.

The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

1. An apparatus, including:
a multi-bit encoder coupled to a multi-tone generator to provide a multi-tone communications signal having a substantially simultaneous multi-tone signaling bandwidth of greater than about 20 percent of an associated carrier frequency.

2. The apparatus of claim 1, wherein the multi-bit encoder is to receive a
first bit stream and to provide a second bit stream having data presented as one or more groups of substantially simultaneous bits.

3. The apparatus of claim 2, wherein the multi-bit encoder includes a shift register.

4. The apparatus of claim 1, wherein the multi-tone generator includes:
a master oscillator and at least one slave oscillator.

5. The apparatus of claim 1, wherein the multi-tone generator is to generate a plurality of tones responsive to the data.

6. The apparatus of claim 5, wherein the plurality of tones includes a number of tones greater than a number of possible states of the data.

7. An apparatus, including:
a plurality of phasor detectors to determine a presence of a plurality of tones included in a multi-tone communications signal by comparing a combined amount of two measured orthogonal signal components to a threshold value.

8. The apparatus of claim 7, wherein at least one of the phasor detectors includes a quadrature detector.

9. The apparatus of claim 7, wherein the two measured orthogonal signal components include a sine component and a cosine component.

10. The apparatus of claim 7, further including:
an amplifier having an averaging automatic gain control to receive the multi-tone communications signal from a distribution module and to apply a substantially equal gain to the plurality of tones.

11. A system, including:
a multi-bit encoder coupled to a multi-tone generator to provide a first multi-tone communications signal having a substantially simultaneous multi-tone signaling bandwidth of greater than about 20 percent of an associated carrier frequency;
a plurality of phasor detectors to determine a presence of a plurality of tones included in a second multi-tone communications signal by comparing a combined amount of two measured orthogonal signal components to a threshold value; and
an omnidirectional antenna to transmit the first multi-tone communications signal and to receive the second multi-tone communications signal.

12. The system of claim 11, further including:
a distribution module to couple to the omnidirectional antenna and to provide the second multi-tone communications signal to the plurality of phasor detectors.

13. The system of claim 11, further including:
a determination module to receive multiple indications of the presence of the plurality of tones from the plurality of phasor detectors and to determine a received data output corresponding to the multiple indications.

14. The system of claim 11, wherein the plurality of tones includes a number of tones at least two times greater than a number of possible states of the data.

15. A method, including:
translating a first bit stream into a multi-tone communications signal having a substantially simultaneous multi-tone signaling bandwidth of greater than about 20 percent of an associated carrier frequency.

16. The method of claim 15, wherein translating the first bit stream further includes:
translating the first bit stream into a second bit stream having data presented as one or more groups of substantially simultaneous bits.

17. The method of claim 16, further including:
translating the second bit stream into the multi-tone communications signal comprising a number of substantially simultaneous tones less than or equal to a maximum number of the substantially simultaneous bits.

18. The method of claim 16, further including:
shifting the first bit stream to provide the second bit stream.

19. A method, including:
receiving a multi-tone communications signal at a plurality of phasor detectors to determine a presence of a number of substantially simultaneous tones included in a multi-tone communications signal.

20. The method of claim 19, further including:
comparing a combined amount of two measured orthogonal signal components in at least one of the number of substantially simultaneous tones to a threshold value.

21. The method of claim 20, further including:
amplifying the multi-tone communications signal using an approximately equal gain prior to the comparing.

22. An article comprising a machine-accessible medium having associated information, wherein the information, when accessed, results in a machine performing:
determining a presence of a plurality of tones included in a multi-tone communications signal by comparing a combined amount of two measured orthogonal signal components to a threshold value.

23. The article of claim 22, wherein determining the presence further includes:
receiving the multi-tone communications signal at a plurality of phasor detectors.

24. The article of claim 22, wherein determining the presence further includes:
amplifying the multi-tone communications signal using an approximately equal gain prior to the comparing.

25. The article of claim 22, further including:
receiving multiple indications of the presence of the plurality of tones from a plurality of phasor detectors.

26. The article of claim 25, further including:
determining a received data output corresponding to the multiple indications.

27. An article comprising a machine-accessible medium having associated information, wherein the information, when accessed, results in a machine performing:
translating a first bit stream into a multi-tone communications signal having a substantially simultaneous multi-tone signaling bandwidth of greater than about 20 percent of an associated carrier frequency.

28. The article of claim 27, wherein translating the first bit stream further includes:
translating the first bit stream into a second bit stream having data presented as at least two groups of substantially simultaneous bits.

29. The article of claim 27, further including:
translating the second bit stream into the multi-tone communications signal comprising a number of substantially simultaneous tones less than or equal to a maximum number of the substantially simultaneous bits.
